(19) United States
(12) Patent Application Publication
(10) Pub. No.: US 2013/0037923 A1
(43) Pub. Date: Feb. 14, 2013

(54) SEMICONDUCTOR PACKAGE AND METHOD OF MANUFACTURING THE SAME

(71) Applicant: Jin O YOO, Hwaseong (KR)

(72) Inventor: Jin O YOO, Hwaseong (KR)

(21) Appl. No.: 13/566,657

(22) Filed: Aug. 3, 2012

(30) Foreign Application Priority Data
Aug. 8, 2011 (KR) 10-2011-0078572

(51) Int. Cl. H01L 23/552; H01L 21/56

(52) U.S. Cl. 257/659; 438/127; 257/E23.114; 257/E21.502

(57) ABSTRACT

There are provided a semiconductor package capable including an electromagnetic wave shielding structure having excellent electromagnetic interference (EMI) shielding characteristics while protecting individual elements therein from impacts, and a method of manufacturing the same. The semiconductor package includes: a substrate having ground electrodes formed on an upper surface thereof; at least one electronic component mounted on the upper surface of the substrate; an underfill resin filled in a space between the electronic component and the substrate; and a conductive shield part formed along an outer surface formed by the electronic component and the underfill resin and electrically connected to the ground electrodes.

### CROSS-REFERENCE TO RELATED APPLICATIONS

This application claims the priority of Korean Patent Application No. 10-2011-0078572 filed on Aug. 8, 2011, in the Korean Intellectual Property Office, the disclosure of which is incorporated herein by reference.

### BACKGROUND OF THE INVENTION

1. Field of the Invention

The present invention relates to a semiconductor package, and more particularly, to a semiconductor package capable of having a reduced thickness while including a shielding member shielding an electromagnetic wave, and a method of manufacturing the same.

2. Description of the Related Art

In the field of electronic products, demand for portable devices has recently increased. Therefore, the miniaturization and lightening of electronic components mounted in the electronic products has also been in continuous demand.

In order to realize the miniaturization and lightening of electronic components, a system on chip (SOC) technology of implementing a plurality of individual elements on one chip, a system in package (SIP) technology of integrating a plurality of individual elements in one package, or the like, as well as a technology of reducing individual mounting component sizes is required.

Particularly, in the case of high frequency semiconductor packages in devices such as a portable television (TV) (a digital multimedia broadcasting (DMB) or digital video broadcasting (DVB)) module or a network module handling high frequency signals, the inclusion of various electromagnetic wave shielding structures in order to excellently implement electromagnetic interference (EMI) shielding characteristics as well as miniaturization has been required.

In a general high frequency semiconductor package according to the related art, after individual elements are mounted on a substrate, the substrate is placed in a mold part which is filled with a resin in order to protect these individual elements. In addition, as a structure for shielding high frequencies, a structure in which a shielding shield is formed on an outer surface of the mold part has been widely known. The shielding shield used in the general high frequency semiconductor package covers all individual elements to thereby provide protection against external impacts, and is electrically connected to a ground to thereby shield electromagnetic waves.

In the case of the semiconductor package according to the related art, since a separate mold part is formed on an outer portion of a semiconductor chip and the shielding shield is then formed, the overall volume of the semiconductor package may be increased.

This defect may hinder the implementation of a thin semiconductor package that has been in recent demand. Therefore, a need exists for a semiconductor package having a significantly reduced volume, particularly, having a significantly reduced thickness, while including a shielding shield, and a method of manufacturing the same.

### SUMMARY OF THE INVENTION

An aspect of the present invention provides a semiconductor package capable of having a reduced volume while including an electromagnetic wave shielding structure having excellent electromagnetic interference (EMI) shielding characteristics, and a method of manufacturing the same.

Another aspect of the present invention provides a semiconductor package in which a shielding shield and a substrate may be easily grounded, and a method of manufacturing the same.

According to an aspect of the present invention, there is provided a semiconductor package including: a substrate having ground electrodes formed on an upper surface thereof; at least one electronic component mounted on the upper surface of the substrate; an underfill resin filled in a space between the electronic component and the substrate; and a conductive shield part formed along an outer surface formed by the electronic component and the underfill resin and electrically connected to the ground electrodes.

The ground electrode may be formed along a circumference of the electronic component.

The shield part may be formed by applying a conductive material to the outer surface using a conformal coating method.

The substrate may have a plurality of electronic components mounted thereon and the shield part may be formed on at least one of the plurality of electronic components.

According to another aspect of the present invention, there is provided a method of manufacturing a semiconductor package, the method including: preparing a substrate having ground electrodes formed on an upper surface thereof; mounting an electronic component on the upper surface of the substrate; filling an underfill resin between the electronic component and the substrate; and forming a shield part on an outer surface formed by the electronic component, the underfill resin, and the ground electrode.

The forming of the shield part may include forming the shield part by a conformal coating method.

The forming of the shield part may include: disposing a mask over the substrate; and applying a conductive material through an opening formed in the mask.

The opening in the mask may have a size corresponding to that of the outer surface formed by the electronic component, the underfill resin, and the ground electrode.

The filling of the underfill resin may include filling the underfill resin between the electronic component and the ground electrode.

The ground electrode may be formed along an edge of the electronic component.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view of a semiconductor package according to an embodiment of the present invention;

FIG. 2 is a partially cut-away perspective view of the semiconductor package shown in FIG. 1;

FIGS. 3 through 8 are cross-sectional views showing a method of manufacturing a semiconductor package according to an embodiment of the present invention in a process sequence; and

FIG. 9 is a flow chart showing a method of manufacturing a semiconductor package according to an embodiment of the present invention.

### DETAILED DESCRIPTION OF THE INVENTION

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention. Therefore, the configurations described in the embodiments and drawings of the present invention are merely embodiments but do not represent all of the technical spirit of the present invention. Thus, the present invention should be construed as including all the changes, equivalents, and substitutions included in the spirit and scope of the present invention at the time of filing this application.

Hereinafter, embodiments of the present invention will be described in detail with reference to the accompanying drawings. At this time, it is noted that like reference numerals denote like elements in appreciating the drawings. Moreover, detailed descriptions related to well-known functions or configurations will be ruled out in order not to unnecessarily obscure the subject matter of the present invention. Based on the same reason, it is to be noted that some components shown in the drawings are exaggerated, omitted or schematically illustrated, and the size of each component does not exactly reflect its real size.

Hereinafter, embodiments of the present invention will be described in detail with reference to the accompanying drawings.

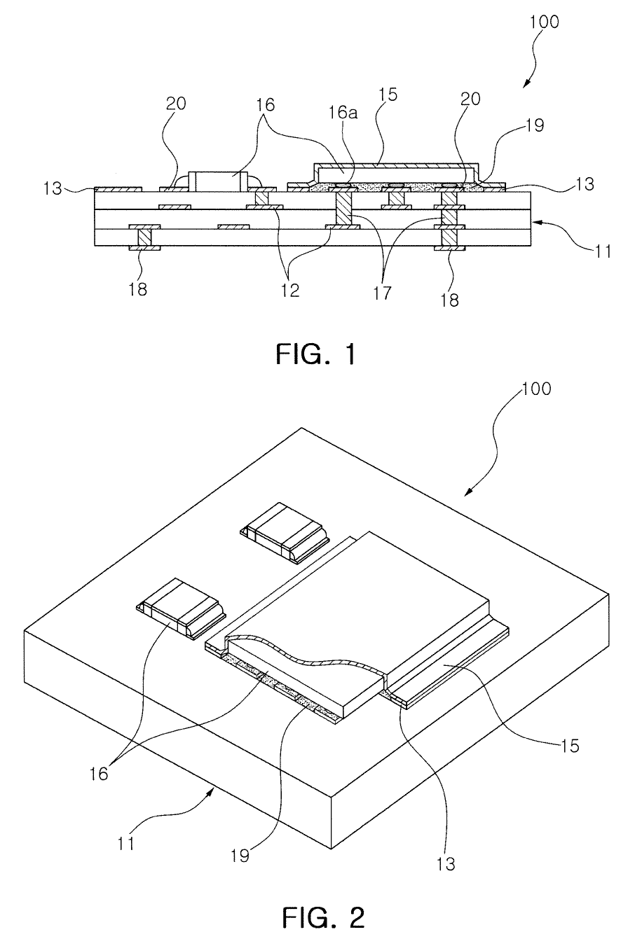

FIG. 1 is a cross-sectional view of a semiconductor package according to an embodiment of the present invention; and FIG. 2 is a partially exploded perspective view showing an inner portion of the semiconductor package shown in FIG. 1.

As shown in FIGS. 1 and 2, a semiconductor package 100 according to the present embodiment may include a substrate 11, ground electrodes 13, electronic components 16, an underfill resin 19, and a shield part 15.

The substrate 11 has at least one electronic component 16 mounted on an upper surface thereof. As the substrate 11, various kinds of substrates (for example, a ceramic substrate, a printed circuit board (PCB), a flexible substrate, or the like) well known in the art may be used.

The substrate 11 may include mounting electrodes 20 or wiring patterns (not shown) formed on an upper surface thereof, wherein the mounting electrode 20 are formed for mounting the electronic components 16 on the substrate 11 and the wiring patterns electrically interconnect the mounting electrodes 20. The substrate 11 may be a multi-layer substrate including a plurality of layers, and circuit patterns 12 for forming electrical connection may be formed between each of the plurality of layers.

In addition, the substrate 11 according to the present embodiment may have ground electrodes 13 formed on the upper surface thereof. The ground electrodes 13 according to the present embodiment may be formed to be long along sides of at least one electronic component 16. These ground electrodes 13 may be formed on each side of the electronic component 16 on which the shield part 15 is formed or be formed along at least one of several sides of the electronic component 16.

FIG. 2 shows a case that the ground electrodes 13 are formed along both opposite sides of the electronic component 16 having a rectangular cross-sectional shape on the upper surface of the substrate 11 by way of example. However, the present invention is not limited thereto. For example, the ground electrodes 13 may be formed along all of four sides of the electronic component 16. In this case, the ground electrodes 13 may be formed to have a rectangular shape along an external shape of the electronic component 16. In addition, when the electronic component 16 has a circular shape, the ground electrodes 13 may have a circular shape or an arc shape.

Meanwhile, the accompanying drawings show that each of ground electrodes 13 is formed to be long at approximately the same width by way of example. However, the present invention is not limited thereto. That is, when the ground electrode 13 and a terminal of the electronic component 16 need to be electrically connected directly to each other, the ground electrode 13 may be configured so that a portion thereof is protruded to a lower portion of the electronic component 16, such that the protruded portion may be electrically connected to the terminal (that is, the ground terminal) of the electronic component 16. In addition, the ground electrodes 13 may be formed to have various forms as needed. For example, the respective ground electrodes 13 may be formed to have different widths.

Further, the substrate 11 according to the present embodiment may include external connection terminals 18 electrically connected to the mounting electrodes 20, the circuit patterns 12, the ground electrodes 13, or the like, formed on the upper surface thereof, and conductive via-holes 17 electrically connecting the mounting electrodes 20, the circuit patterns 12, the ground electrodes 13, or the like, to the external connection terminals 18. In addition, the substrate 11 according to the present embodiment may include cavities formed therein, wherein the cavities allow the electronic components to be mounted at an inner portion of the substrate 11.

The electronic components 16 may include various elements such as a passive element and an active element and be any electronic element capable of being mounted on the substrate 11 or capable of being embedded in the substrate 11.

The electronic component 16 may include external connection terminals 16a and be electrically connected to the substrate 11 through the external connection terminals 16a. Here, the underfill resin 19 may be filled in a space between the electronic component 16 and the substrate 11 and between the external connection terminals 16a.

The underfill resin 19 is provided in order to protect the external connection terminals 16a of the electronic component 16 and improve adhesion between the electronic component 16 and the substrate 11, thereby increasing reliability. As the underfill resin 19, an epoxy resin, or the like, may be used. However, the underfill resin 19 is not limited thereto.

The underfill resin 19 may be filled in a space between the electronic component 16 and the substrate 11. In addition, the underfill resin 19 may be also filled in a space between the electronic component 16 and the ground electrode 13. Here, the underfill resin 19 may be formed in a space between the electronic component 16 and the ground electrode 13 so as to expose the ground electrode 13 exposed to the outside without completely covering the ground electrodes 13 disposed on the sides of the electronic component 16.

In addition, the underfill resin 19 according to the present embodiment may form an outer surface continuously connecting the sides of the electronic component 16 and the ground electrode 13 of the substrate 11 to each other. The outer surface of the electronic component 16 and the ground electrode 13 may be formed in a form in which it is continuously connected without being disconnected by a gap, an empty space, or the like, by the underfill resin 19.

A shield part 15 to be described below may be formed on the outer surface. A detailed description of the shield part 15 will be provided below.

At least one of the electronic components 16 according to the present embodiment may include the shield part 15 formed on an outer surface thereof.

The shield part 15 may be formed on the outer surface of the electronic component 16 in a form in which it encloses an outer portion of the electronic component 16 to thereby shield an unnecessary electromagnetic wave introduced from the outside of the substrate 11. In addition, the shield part 15 blocks an electromagnetic wave generated in the electronic component 16 from being radiated to the outside. The shield part 15 may be formed to cover the entire outer surface of the electronic component 16.

The shield part 15 according to the present embodiment may be selectively formed in an electronic component requiring electromagnetic wave shielding. Particularly, the shield part 15 may be easily formed in a flip chip type of electronic component 16.

In this case, the shield part 15 may be formed along the outer surface formed by the electronic component and the underfill resin filled in a space between the electronic component and the substrate and may be electrically connected to the ground electrode 13 formed on the substrate 11.

Therefore, the shield part 15 according to the present embodiment may be formed in a form in which it encloses the entire outer surface of the electronic component 16, the underfill resin 19, and the ground electrode 13.

The shield part 15 according to the present embodiment may be formed of various materials having conductivity. For example, the shield part 15 according to the present embodiment may be formed of a resin material containing a conductive powder or be completed directly by forming a metal thin layer. In the case of forming the metal thin layer, various technologies such as a sputtering method, a vapor deposition method, an electroplating method, an electroless plating method, and the like, may be used.

In addition, the shield part 15 may be a metal thin layer formed by a conformal coating method. The conformal coating method may be used to form a uniform application layer and may have a low cost required for equipment investment. In addition, the shield part 15 may be a metal thin layer formed by a painting method or a screen printing method.

In the semiconductor package 100 according to the present embodiment configured as described above, the shield part 15 may be selectively formed only on a specific electronic component 16 among several electronic components 16 mounted on the substrate 11. Therefore, unlike the case according to the related art, the entire semiconductor package needs not to be sealed, such that the semiconductor package may be easily manufactured. In addition, a sealing part is omitted, such that a size, that is, a thickness of the semiconductor package may be reduced.

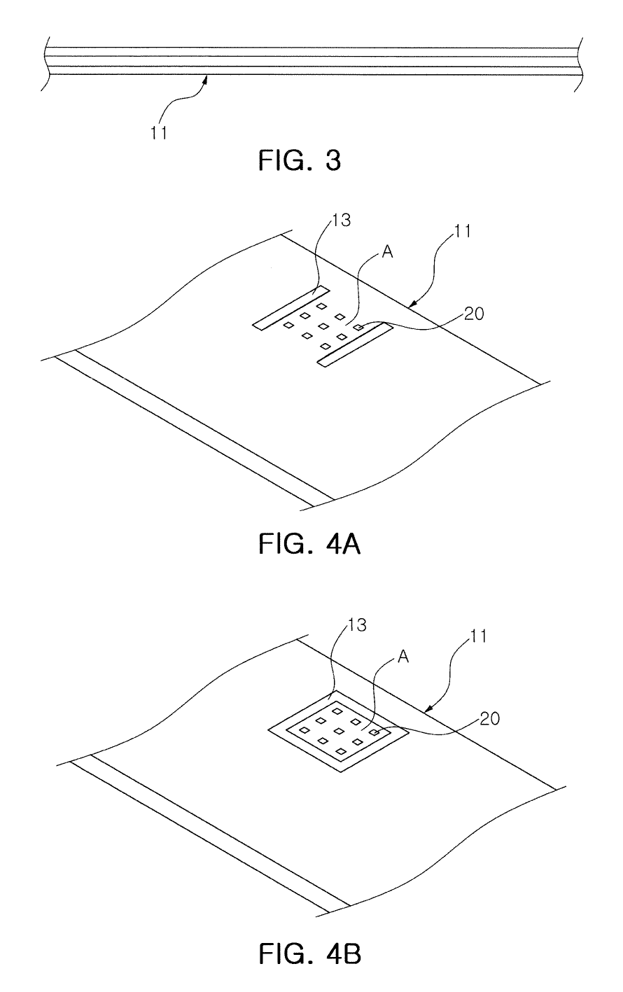

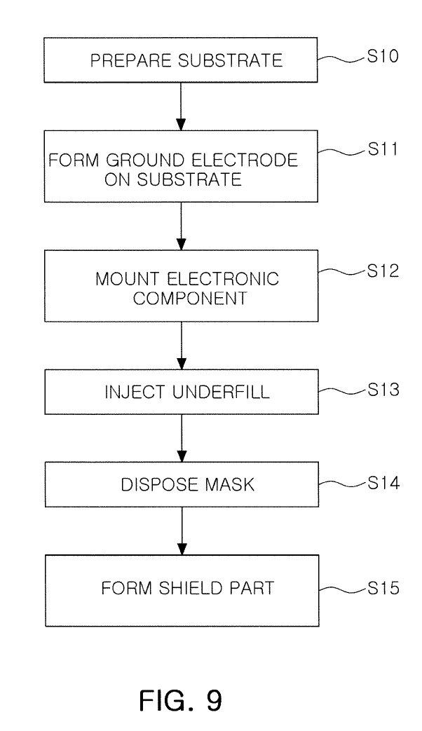

FIGS. 3 through 8 are cross-sectional views showing a method of manufacturing a semiconductor package according to an embodiment of the present invention in a process sequence; and FIG. 9 is a flow chart showing the method of manufacturing a semiconductor package according to an embodiment of the present invention.

First referring to FIG. 3 based on FIG. 9, the method of manufacturing a semiconductor package according to the embodiment of the present invention starts from operation (S10) of preparing a substrate 11.

The substrate 11 according to the present embodiment may be a multi-layer substrate 11 including a plurality of layers, and circuit patterns 12 electrically connected to each other may be formed between each of the plurality of layers. More specifically, the substrate 11 may include the circuit patterns 12, the external connection terminal 18, the mounting electrodes 20, the via holes 17, and the like, shown in FIG. 1.

Then, as shown in FIG. 4A, operation (S11) of forming ground electrodes 13 on an upper surface of the substrate 11 may be performed. The ground electrode 13 may be formed corresponding to a mounting area A of a specific electronic component 16 on which a shield part 15 (See FIG. 1) is formed among electronic components 16 mounted on the substrate 11, as described above. That is, when the specific electronic component 16 on which the shield part is formed is mounted on the substrate 11, the ground electrodes 13 may be disposed along sides of the specific electronic component 16.

Here, the ground electrodes 13 may be formed in a straight line form in which they are disposed to be in parallel with each other as shown in FIG. 4A. However, the present invention is not limited thereto. That is, the ground electrodes 13 may also be formed in a rectangular shape along a circumference of the mounting area A as shown in FIG. 4B. In this case, when the specific electronic component 16 on which the shield part is formed is mounted on the substrate 11, the ground electrode 13 may be disposed along the entire edge of the specific electronic component 16.

Meanwhile, a method of forming the ground electrode 13 on the substrate 11 may be the same as a general method of forming circuit patterns. Therefore, a detailed description thereof will be omitted.

Further, in the method of manufacturing a semiconductor package according to the present embodiment, the ground electrode 13 may also be previously formed on the substrate 11 at the time of manufacturing of the substrate 11. In this case, the above-mentioned operation (S11) of forming the ground electrode 13 may be omitted.

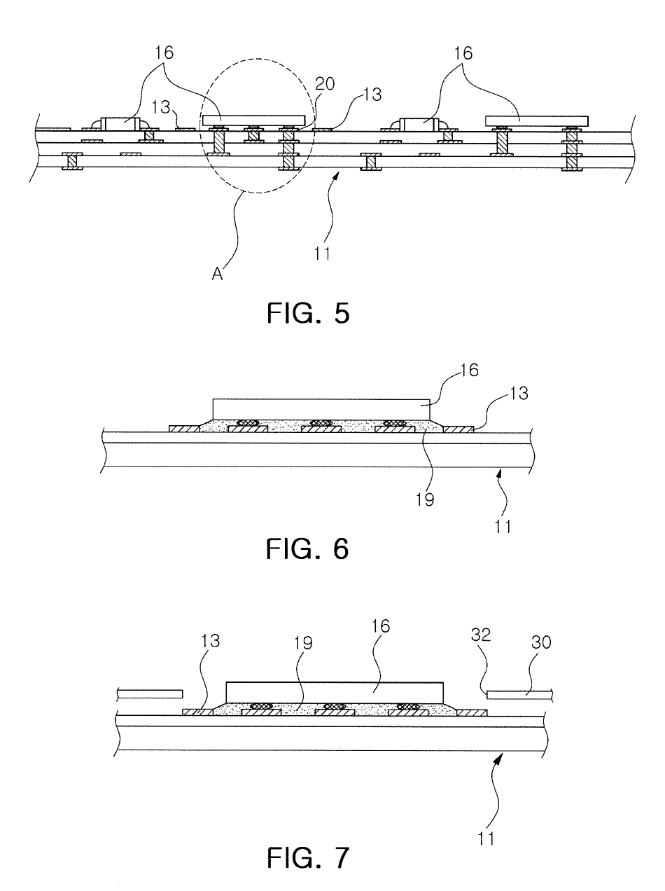

Next, as shown in FIG. 5, operation (S12) of mounting several electronic components 16 on one surface of the substrate 11 may be performed. Here, each of the electronic components 16 may be mounted on corresponding mounting areas of the substrate 11. Therefore, the above-mentioned specific electronic component 16 on which the shield part is formed may be also mounted while being disposed on the mounting area A (See FIG. 4A), that is, between the ground electrodes 13.

Thereafter, as shown in FIG. 6, operation (S13) of injecting and filling an underfill resin 19 between the substrate 11 and the electronic component 16 may be performed. The underfill resin 19 may be injected between the substrate 11 and the electronic component 16 in a liquid state and be then cured through a separate curing process.

Here, as described above, the underfill resin 19 may be filled in a space between the substrate 11 and the electronic component 16 so that at least a portion of the ground electrode 13 of the substrate 11 is exposed.

The underfill resin 19 may be formed with respect to several electronic components 16 mounted on the substrate 11. The present embodiment describes a case in which the underfill resin 19 is formed between the specific electronic component 16 on which the shield part is formed and the substrate 11 by way of example. However, the present invention is not limited thereto. That is, the underfill resin may be formed in various forms as needed in spaces between the several electronic components 16 mounted on the substrate 11 and the substrate 11.

Then, as shown in FIG. 7, operation (S14) of disposing a mask 30 over the substrate 11 may be performed. The mask 30 used in the present operation includes an opening 32 formed at an area in which the shield part 15 is formed. Therefore, when the mask 30 is disposed over the substrate 11, the specific electronic component 16 on which the shield part is to be formed, the underfill resin 19 filled on a lower portion of the specific electronic component 16, and the ground electrodes 13 are exposed through the opening 32.

The mask 30 may be formed of any material and be formed in any form as long as the area at which the shield part is formed may be exposed to the outside. For example, the mask 30 may be formed in a flat plate form as shown in FIG. 7 or be formed in an adhesive tape form to thereby be adhered to the substrate 11.

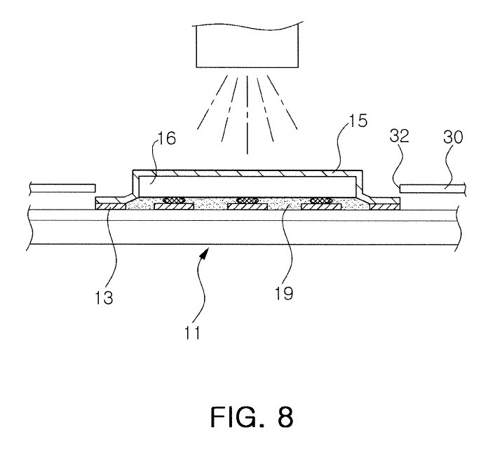

Next, as shown in FIG. 8, operation (S14) of forming the shield part 15 may be performed. According to the present embodiment, the shield part 15 may be formed by spraying a conductive material in a spray form on an upper portion of the mask 30.

Therefore, the shield part 15 may be formed only on a portion exposed through the opening 32 of the mask 30, that is, on an outer surface formed by the specific electronic component 16, the underfill resin 19 filled on the lower portion of the specific electronic component 16, and the ground electrodes 13.

As described above, the shield part 15 according to the present embodiment may be easily formed by applying a conformal coating method. Therefore, the shield part 15 may be implemented in a form of a metal thin layer.

The conformal coating method may be appropriate to form a uniform application layer and may have a lower equipment investment cost, more excellent productivity, more environment-friendly characteristics as compared to the other process of forming a thin layer (for example, an electroplating method, an electroless plating method, a sputtering method).

However, the present invention is not limited thereto. That is, the shield part may also be formed by a screen printing method or a painting method. When the screen printing method or the painting method is used, the mask 30 may be formed in an adhesive tape form.

Meanwhile, in the method of manufacturing a semiconductor package according to an embodiment of the present invention, after the shield part 15 is formed, a plasma processing process may be performed on the shield part 15 in order to improve abrasion resistance and corrosion resistance of a surface of the shield part 15.

Then, after the shield part 15 is completely cured, the mask 30 is removed, such that the semiconductor package 100 according to the present embodiment is completed.

In the method of manufacturing a semiconductor package according to the embodiment of the present invention configured as described above, the shield part may be formed directly on the individual electronic components without forming a sealing part or a molding, unlike the case according to the related art. Therefore, since a process of forming and curing the sealing part may be omitted, a process of manufacturing the semiconductor package may be simplified.

In addition, since the shield part may be selectively formed only on a required portion on the substrate using the mask, the shield part may be very easily formed as compared to the case according to the related art.

Further, in the semiconductor package according to the embodiment of the present invention, the sealing part enclosing the electronic components is not formed, such that a height of the semiconductor package may be reduced by a thickness of the sealing part.

Further, in the case according to the related art in which the shield part is formed of a metal case, or the like, the shield part and the electronic component have a gap of 100 to 200 μm therebetween, and the shield part itself has a thickness of 100 to 200 μm, such that an upper surface of the electronic component and an outer surface of the shield part have the entire thickness of 200 to 400 μm therebetween.

However, in the case of the semiconductor package according to the embodiment of the present invention, the shield part may be formed directly on the outer surface, that is, the upper surface of the electronic component and may be formed in an application form, that is, a form of a coating layer, such that only 10 to 30 μm, which is a thickness of the shield part, is actually increased from the upper surface of the electronic component.

As described above, since the semiconductor package according to the embodiment of the present invention may have a significantly reduced height, it may be easily mounted on a thin electronic product.

As set forth above, with the semiconductor package and the method of manufacturing the same according to the embodiment of the present invention, the ground electrode formed on the upper surface of the substrate may be used to ground the shield part for shielding an electromagnetic wave, whereby the shield part may be easily grounded.

In addition, in the method of manufacturing a semiconductor package according to the embodiments of the present invention, the shield part may be formed directly on the individual electronic components without forming a sealing part or a molding, unlike the case according to the related art. Therefore, since a process of forming and curing the sealing part may be omitted, a process of manufacturing the semiconductor package may be simplified.

Further, in the semiconductor package according to the embodiment of the present invention, the sealing part enclosing the electronic components may not be formed, such that a height of the semiconductor package may be reduced by a thickness of the sealing part.

Particularly, in the semiconductor package according to the embodiment of the present invention, the shield part may be formed directly on the outer surface, that is, the upper surface of the electronic component and may be formed in an application form, that is, a form of a coating layer, such that a height of the semiconductor package is actually increased by a thickness of the shield part.

Therefore, since the semiconductor package may have a significantly reduced height, it may be easily mounted on a thin electronic product.

Further, since the shield part may be selectively formed only on a required portion on the substrate using the mask, the shield part may be very easily formed as compared to the case according to the related art.

Meanwhile, the semiconductor package and the method of manufacturing the same according to the present invention described above are not limited to the above-mentioned embodiments but may be variously applied. In addition, although the above-mentioned embodiments have described the semiconductor package including the shield part by way of example, the present invention is not limited thereto but may be variously applied to any device including the shield part.

While the present invention has been shown and described in connection with the embodiments, it will be apparent to those skilled in the art that modifications and variations can be made without departing from the spirit and scope of the invention as defined by the appended claims.

What is claimed is:

1. A semiconductor package comprising:
a substrate having ground electrodes formed on an upper surface thereof;
at least one electronic component mounted on the upper surface of the substrate;
an underfill resin filled in a space between the electronic component and the substrate; and
a conductive shield part formed along an outer surface formed by the electronic component and the underfill resin and electrically connected to the ground electrodes.

2. The semiconductor package of claim 1, wherein the ground electrode is formed along a circumference of the electronic component.

3. The semiconductor package of claim 1, wherein the shield part is formed by applying a conductive material to the outer surface using a conformal coating method.

4. The semiconductor package of claim 1, wherein the substrate has a plurality of electronic components mounted thereon and the shield part is formed on at least one of the plurality of electronic components.

5. A method of manufacturing a semiconductor package, the method comprising:
preparing a substrate having ground electrodes formed on an upper surface thereof;
mounting an electronic component on the upper surface of the substrate;
filling an underfill resin between the electronic component and the substrate; and
forming a shield part on an outer surface formed by the electronic component, the underfill resin, and the ground electrode.

6. The method of claim 5, wherein the forming of the shield part includes forming the shield part by a conformal coating method.

7. The method of claim 5, wherein the forming of the shield part includes:
disposing a mask over the substrate; and
applying a conductive material through an opening formed in the mask.

8. The method of claim 7, wherein the opening in the mask has a size corresponding to that of the outer surface formed by the electronic component, the underfill resin, and the ground electrode.

9. The method of claim 5, wherein the filling of the underfill resin includes filling the underfill resin between the electronic component and the ground electrode.

10. The method of claim 5, wherein the ground electrode is formed along an edge of the electronic component.
